(19) United States
(12) Patent Application Publication
(10) Pub. No.: US 2024/0242980 A1
(43) Pub. Date: Jul. 18, 2024

(54) SUBSTRATE ETCHING APPARATUS AND SUBSTRATE ETCHING METHOD

(71) Applicant: Samsung Display Co., LTD., Yongin-si (KR)

(72) Inventors: Yonghyun KIM, Yongin-si (KR); Kyu-Bum KIM, Yongin-si (KR); Seung Ho MYOUNG, Yongin-si (KR); Yeongmin KIM, Yongin-si (KR); Ju Yeong YUN, Yongin-si (KR); Jungwoo CHOI, Yongin-si (KR)

(21) Appl. No.: 18/390,323

(22) Filed: Dec. 20, 2023

(30) Foreign Application Priority Data
Jan. 13, 2023 (KR) 10-2023-0005601

(51) Int. Cl. H01L 21/67; H01L 21/677; H01L 21/687

(52) U.S. Cl. CPC H01L 21/67069; H01L 21/6719; H01L 21/67706; H01L 21/68764

(57) ABSTRACT

A substrate etching apparatus includes: a stage moving part for supporting a substrate carrier to which a substrate is attached in a vertical direction and for moving the substrate carrier to which the substrate is attached in a horizontal direction; a substrate carrier loading part positioned in a first region in the horizontal direction and for loading the substrate carrier to which the substrate is attached to the stage moving part; and an etching part positioned in a second region adjacent to the first region in the horizontal direction and for etching the substrate attached to the substrate carrier supported on the stage moving part in the vertical direction.

This application claims priority to Korean Patent Application No. 10-2023-0005601, filed on Jan. 13, 2023, and all the benefits accruing therefrom under 35 U.S.C. § 119, the content of which in its entirety is herein incorporated by reference.

### BACKGROUND

### (a) Field

The present disclosure relates to a substrate etching apparatus and a substrate etching method.

### (b) Description of the Related Art

In general, an organic light emitting device is manufactured by performing a patterning process, an organic film deposition process, an etching process, an encapsulation process, and the like on a substrate.

The etching process is a process of etching and removing some of the structures formed on the substrate by using a substrate etching apparatus.

Conventionally, the substrate etching apparatus separates the substrate attached to a substrate carrier transported from a previous process from the substrate carrier to be placed on a seating part inside a chamber, rotates the seating part based on the horizontal direction so that the surface of the substrate seated on the seating part faces downward, and etches the substrate by irradiating a laser beam from the lower side of the substrate.

However, the conventional substrate etching apparatus requires a space and rotation means for separating the substrate from the substrate carrier to place the substrate on the seating part, and rotating the substrate seated on the seating part around the horizontal direction.

### SUMMARY

Embodiments are intended to provide a substrate etching apparatus in which an etching process is performed in a state in which a substrate is attached to a substrate carrier and supported in a vertical direction, and a substrate etching method not separating the substrate attached to the substrate carrier transported from the previous process from the substrate carrier and rotating around the horizontal direction so that the surface of the substrate faces downward.

A substrate etching apparatus according to an aspect includes: a stage moving part for supporting a substrate carrier, to which a substrate is attached, in a vertical direction and for moving the substrate carrier, to which the substrate is attached, in a horizontal direction; a substrate carrier loading part positioned in a first region in the horizontal direction and for loading the substrate carrier, to which the substrate is attached, to the stage moving part; and an etching part positioned in a second region adjacent to the first region in the horizontal direction and for etching the substrate attached to the substrate carrier supported on the stage moving part in the vertical direction.

The stage moving part may include: a stage part for supporting the substrate carrier in the vertical direction; a frame part for guiding the stage part in the horizontal direction; and a moving part for supporting the stage part and being guided by the frame part to move in the horizontal direction.

The stage part may not be rotated.

The frame part may include: a first rail part positioned on a lower rear of the stage part, extending in the horizontal direction and for supporting the moving part; a second rail part positioned on an upper rear of the stage part, extending in the horizontal direction and for supporting the moving part; and a fixing part, which fixes the first rail part and the second rail part.

The first rail part and the second rail part may support the moving part in the vertical direction.

The first rail part may support the moving part in the vertical direction, and the second rail part may support the moving part in a cross direction intersecting the vertical direction and the horizontal direction.

The first rail part and the second rail part may support the moving part in a cross direction intersecting the vertical direction and the horizontal direction.

The fixing part may include at least one of a granite frame, a rectangular tube frame, and a solid frame.

The substrate carrier loading part may rotate the substrate carrier to which the substrate is attached around the horizontal direction to be aligned in the vertical direction.

The substrate carrier to which the substrate is attached may be put into the substrate carrier loading part in a tilted state with a predetermined angle with respect to the vertical direction.

The substrate carrier loading part may include: a supporting part for supporting the substrate carrier; a rotation part for rotating the lower portion of the supporting part around the horizontal direction; and a tilt driving part for moving the upper part of the supporting part in a cross direction intersecting the vertical direction and the horizontal direction.

The substrate carrier loading part may move the substrate carrier to which the substrate is attached in the vertical direction and then in the cross direction such that the substrate carrier is loaded to the stage moving part.

The etching part may use a laser beam to etch the substrate attached to the substrate carrier.

The etching part may include: a measuring part, which measures a flatness of the substrate attached to the substrate carrier in the vertical direction and checks the etching state of the substrate by the laser beam; and a processing part, which irradiates the laser beam to the substrate attached to the substrate carrier and checks alignment of the substrate attached to the substrate carrier based on the laser beam.

The processing part may perform auto focus on the laser beam irradiated on the substrate using the flatness of the substrate measured by the measuring part.

A substrate etching method according to another aspect includes: inputting a substrate carrier, to which a substrate is attached and which is supported in a vertical direction, into a substrate carrier loading part positioned in a first region in a horizontal direction; loading the substrate carrier to which the substrate is attached from the substrate carrier loading part to a stage moving part; and moving the substrate carrier, to which the substrate is attached and which is supported to the stage moving part in the vertical direction, into a second region adjacent to the first region in the horizontal direction to etch the substrate attached to the substrate carrier by using an etching part positioned in the second region.

The substrate carrier to which the substrate is attached may be put into the substrate carrier loading part in a tilted state with a predetermined angle with respect to the vertical direction.

The substrate carrier loading part may rotate the substrate carrier to which the substrate is attached around the horizontal direction to be aligned in the vertical direction, move the substrate carrier in the vertical direction, and move the substrate carrier in a cross direction intersecting the vertical direction and the horizontal direction such that the substrate carrier is loaded to the stage moving part.

The etching part may use a laser beam to etch the substrate attached to the substrate carrier.

The etching part may perform auto focus on the laser beam irradiated onto the substrate by using a flatness of the substrate attached to the substrate carrier.

According to embodiments, the substrate etching apparatus in which the etching process is performed in a state in which the substrate is attached to the substrate carrier and supported in the vertical direction, and the substrate etching method not separating the substrate attached to the substrate carrier transported from the previous process from the substrate carrier and rotating around the horizontal direction so that the surface of the substrate faces downward, are provided.

### BRIEF DESCRIPTION OF THE DRAWINGS

FIG. 1 is a perspective view showing a substrate etching apparatus according to an embodiment.

FIG. 2 is a perspective view showing a stage moving part and an etching part of a substrate etching apparatus according to an embodiment.

FIG. 3 is a side view showing one example of a frame part and a moving part of a stage moving part of a substrate etching apparatus according to an embodiment.

FIG. 4 is a side view showing another example of a frame part and a moving part of a stage moving part of a substrate etching apparatus according to an embodiment.

FIG. 5 is a side view showing another example of a frame part and a moving part of a stage moving part of a substrate etching apparatus according to an embodiment.

FIG. 6 is a perspective view showing one example of a frame part of a stage moving part of a substrate etching apparatus according to an embodiment.

FIG. 7 is a perspective view showing another example of a frame part of a stage moving part of a substrate etching apparatus according to an embodiment.

FIG. 8 is a perspective view showing another example of a frame part of a stage moving part of a substrate etching apparatus according to an embodiment.

FIG. 9 is a side view showing a substrate carrier loading part of a substrate etching apparatus according to an embodiment.

FIG. 10 is a view showing one example of a processing part of an etching part of a substrate etching apparatus according to an embodiment.

FIG. 11 is a flowchart showing a substrate etching method according to another embodiment.

FIG. 12 to FIG. 19 are perspective views to explain a substrate etching method according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are exaggeratedly displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise”, and variations such as “comprises” or “comprising”, will be understood to imply the inclusion of stated elements but not the exclusion of any other elements.

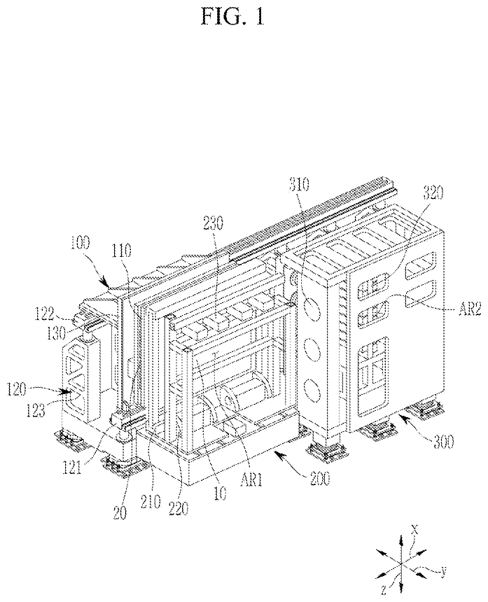

Hereinafter, a substrate etching apparatus according to an embodiment is described with reference to FIG. 1 to FIG. 10. A substrate etching apparatus according to an embodiment may be an apparatus for etching a substrate, but is not limited thereto and may be an apparatus for performing various well-known processing on a substrate.

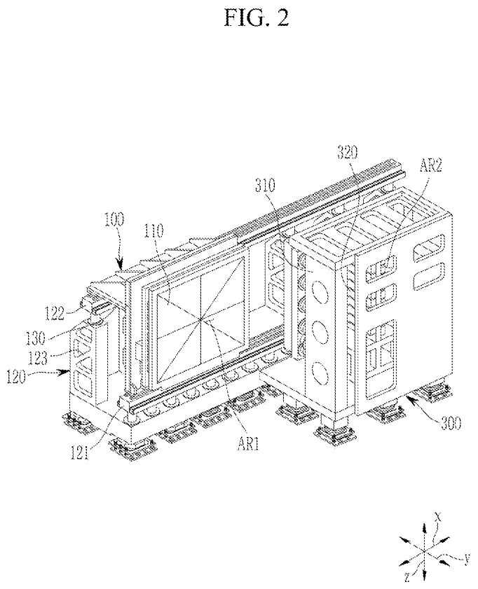

FIG. 1 is a perspective view of a substrate etching apparatus according to an embodiment. FIG. 2 is a perspective view of a stage moving part and an etching part of a substrate etching apparatus according to an embodiment.

Referring to FIG. 1 and FIG. 2, a substrate etching apparatus according to an embodiment etches a substrate 10 attached to a substrate carrier 20 transferred from a previous process, such as a process of depositing an organic layer on the substrate 10, in a state that the substrate 10 is not separated from the substrate carrier 20 and is attached to the substrate carrier 20.

Here, the etching may include using a laser drill that exposes a pattern formed on the substrate 10 by forming a hole in the organic layer deposited on the substrate 10 using a laser beam, but is not limited thereto.

The substrate etching apparatus includes a stage moving part 100, a substrate carrier loading part 200, and an etching part 300.

The stage moving part 100 supports in the vertical direction z the substrate carrier 20 to which the substrate 10 loaded from the substrate carrier loading part 200 is attached. The stage moving part 100 moves in the horizontal direction x the substrate carrier 20 to which the substrate 10 is attached. The stage moving part 100 moves the substrate carrier 20 to which the substrate 10 is attached to a first region AR1 or to a second region AR2, where the first region AR1 and the second region AR2 are adjacent to each other in the horizontal direction x. Here, the substrate carrier loading part 200 is positioned in the first region AR1, and the etching part 300 is positioned in the second region AR2.

Here, the vertical direction z includes a first direction perpendicular to the ground, but is not limited thereto. In addition, the horizontal direction x includes a second direction crossing the vertical direction z, but is not limited thereto. In addition, the crossing direction y includes a third direction crossing the horizontal direction x and the vertical direction z, but is not limited thereto.

The stage moving part 100 includes a stage part 110, a frame part 120, and a moving part 130.

The stage part 110 supports the substrate carrier 20 to which the substrate 10 is attached in the vertical direction z. The stage part 110 may include various supporting means such as various known electrostatic chucks, clamps, and jigs. The stage part 110 does not rotate. Here, the non-rotation may include non-rotation of the stage part 110 around the horizontal direction x and the vertical direction z, but is not limited thereto.

The frame part 120 guides the stage part 110 in the horizontal direction x. The frame part 120 may include various known rail parts capable of guiding the stage part 110 in the horizontal direction x.

The frame part 120 includes a first rail part 121, a second rail part 122, and a fixing part 123.

The first rail part 121 may be positioned on the lower rear of the stage part 110 and extends in the horizontal direction x. The first rail part 121 supports the moving part 130 and guides the movement of the moving part 130 in the horizontal direction x.

The second rail part 122 may be positioned in the upper rear of the stage part 110 and extends in the horizontal direction x. The second rail part 122 supports the moving part 130 and guides the movement of the moving part 130 in the horizontal direction x.

The fixing part 123 fixes the first rail part 121 and the second rail part 122 in the form of a frame.

The moving part 130 supports the stage part 110 and moves in the horizontal direction x. The moving part 130 is guided by the first rail part 121 and the second rail part 122 of the frame part 120 and moves in the horizontal direction x. The moving part 130 may include various known moving means.

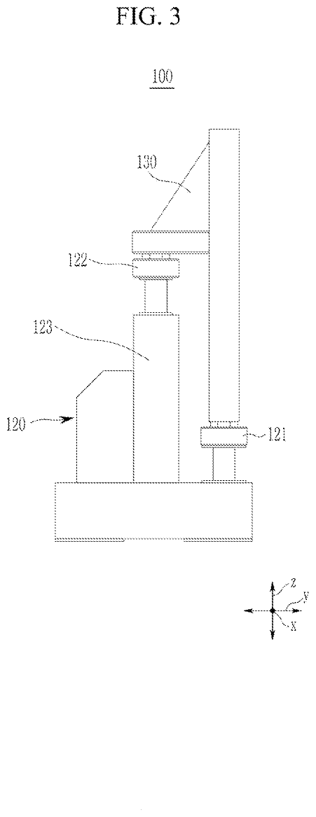

FIG. 3 is a side view showing an example of a frame part and a moving part of a stage moving part of a substrate etching apparatus according to an embodiment.

Referring to FIG. 3, as an example of the frame part 120 and the moving part 130, the first rail part 121 and the second rail part 122 support the moving part 130 in the vertical direction z. Since the first rail part 121 and the second rail part 122 support the moving part 130 in the vertical direction z, a fluctuation of the moving part 130 in an unintended direction (i.e., a direction different from the horizontal direction x) when the moving part 130 moves in the horizontal direction x may be minimized.

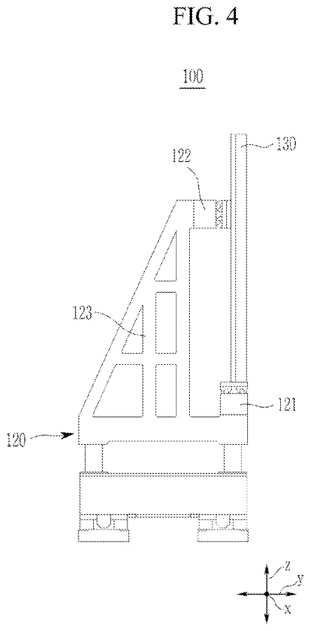

FIG. 4 is a side view showing another example of a frame part and a moving part of a stage moving part of a substrate etching apparatus according to an embodiment.

Referring to FIG. 4, as another example of the frame part 120 and the moving part 130, the first rail part 121 supports the moving part 130 in the vertical direction z, and the second rail part 122 supports the moving part 130 in the crossing direction y. As the first rail part 121 supports the moving part 130 in the vertical direction z and the second rail part 122 supports the moving part 130 in the cross direction y, the fluctuation of the moving part 130 in an unintended direction (i.e., a direction different from the horizontal direction x) may be minimized when the moving part 130 moves in the horizontal direction x.

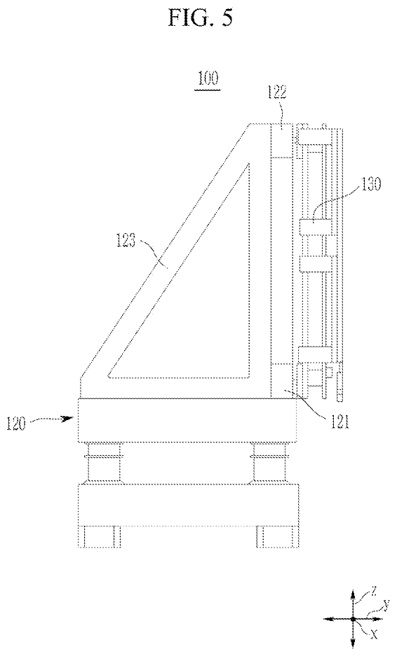

FIG. 5 is a side view showing another example of a frame part and a moving part of a stage moving part of a substrate etching apparatus according to an embodiment.

Referring to FIG. 5, as another example of the frame part 120 and the moving part 130, the first rail part 121 and the second rail part 122 support the moving part 130 in the crossing direction y. Since the first rail part 121 and the second rail part 122 support the moving part 130 in the crossing direction y, the fluctuation of the moving part 130 in an unintended direction (i.e., a direction different from the horizontal direction x) when the moving part 130 moves in the horizontal direction x may be minimized.

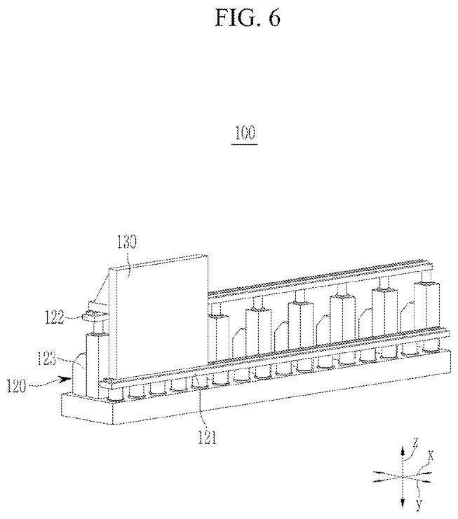

FIG. 6 is a perspective view of an example of a frame part of a stage moving part of a substrate etching apparatus according to an embodiment.

Referring to FIG. 6, as an example of the frame part 120 of the stage moving part 100, the fixing part 123 of the frame part 120 includes a granite frame in a form of a frame. As the fixing part 123 includes the granite frame, the weight and size of the frame part 120 may be minimized, and the rigidity of the frame part 120 may be improved, thereby minimizing a deformation of the frame part 120.

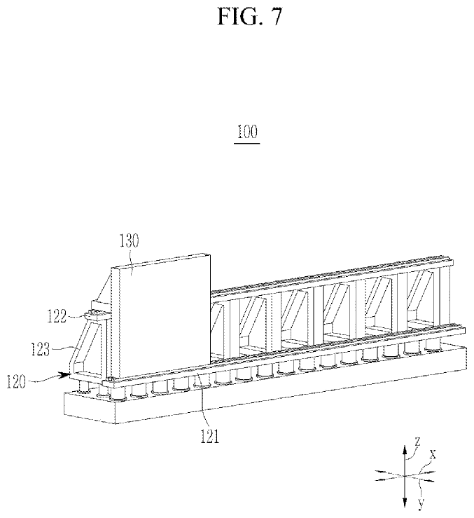

FIG. 7 is a perspective view showing another example of a frame part of a stage moving part of a substrate etching apparatus according to an embodiment.

Referring to FIG. 7, as another example of the frame part 120 of the stage moving part 100, the fixing part 123 of the frame part 120 includes a solid frame in a form of a frame. The inside of the solid frame may be filled with the same material as the material at the outer surface of the solid frame. By including the solid frame in the fixing part 123, the rigidity of the frame part 120 may be improved, so that the deformation of the frame part 120 may be minimized.

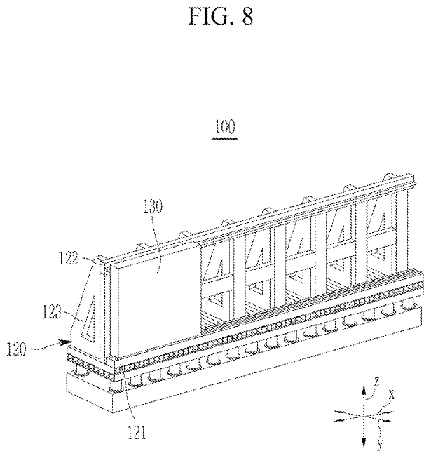

FIG. 8 is a perspective view showing another example of a frame part of a stage moving part of a substrate etching apparatus according to an embodiment.

Referring to FIG. 8, as another example of the frame part 120 of the stage moving part 100, the fixing part 123 of the frame part 120 includes a rectangular tube frame in the form of a frame. The inside of the rectangular tube frame may be empty. Since the fixing part 123 includes the rectangular tube frame, the weight of the frame part 120 is minimized.

As such, the fixing part 123 of the frame part 120 may include at least one of the granite frame, the rectangular tube frame, and the solid frame.

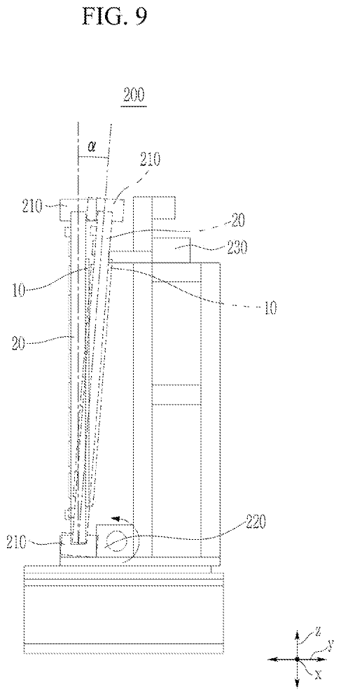

FIG. 9 is a side view showing a substrate carrier loading part of a substrate etching apparatus according to an embodiment.

Referring to FIG. 9 and FIG. 1, the substrate carrier loading part 200 is positioned on the first region AR1 with respect to the horizontal direction x. The substrate carrier loading part 200 loads to the stage moving part 100 the substrate carrier 20 to which the substrate 10 transferred from the previous process is attached. The substrate carrier loading part 200 may align the substrate carrier 20 to which the substrate 10 is attached in the vertical direction z by rotating the substrate carrier 20 around the horizontal direction x. The substrate carrier 20 to which the substrate 10 is attached from the previous process including an organic layer deposition process and the like may be loaded into the substrate carrier loading part 200 in a state of tilting at a predetermined angle with respect to the vertical direction z.

The substrate carrier loading part 200 includes a supporting part 210, a rotation part 220, and a tilt driving part 230.

The supporting part 210 supports the substrate carrier 20 to which the substrate 10 is attached. The supporting part 210 may support the edge of the substrate carrier 20. Specifically, the supporting part 210 may support the upper and lower edges of the substrate carrier 20.

The rotation part 220 rotates the lower part of the supporting part 210 around the horizontal direction x, and may include rotation means such as various well-known motors.

The tilt driving unit 230 moves the upper portion of the support unit 210 in a cross direction (y) crossing the vertical direction (z) and the horizontal direction (x).

By rotating the lower part of the supporting part 210 around the horizontal direction x by the rotation part 220, and moving the upper part of the supporting part 210 in the cross direction y by the tilt driving part 230, the substrate carrier 20, to which the substrate 10 is attached, and that is loaded in the state that is tilted by the predetermined angle α with respect to the vertical direction z into the substrate carrier loading part 200 from the previous process, is supported by the supporting part 210, and aligned in the vertical direction z.

The substrate carrier loading part 200 may move the substrate carriers 20 to which the substrates 10 are attached and aligned in the vertical direction z and move in the cross direction y so as to be loaded to the stage moving part 100. The substrate carrier loading part 200 may include various known vertical movement means and various horizontal movement means.

Referring back to FIG. 1 and FIG. 2, the etching part 300 is positioned in the second region AR2 adjacent to the first region AR1 where the substrate carrier loading part 200 is positioned in the horizontal direction x. The etching part 300 etches the substrate 10 attached to the substrate carrier 20 supported in the vertical direction z on the stage moving part 100.

The etching part 300 may etch the substrate 10 attached to the substrate carrier 20 by using a laser beam. For example, the etching part 300 may laser drill the organic layer deposited on the substrate 10 by using a laser beam, but is not limited thereto.

The etching part 300 includes a measuring part 310 and a processing part 320.

The measuring part 310 may measure the flatness of the substrate 10 attached to the substrate carrier 20 in the vertical direction z and check the etching state of the substrate 10 by the laser beam. The measuring part 310 may include various well-known flatness measuring sensors such as a laser distance sensor (“LDS”) and a camera for checking an etching state.

The processing part 320 may irradiate a laser beam to the substrate 10 attached to the substrate carrier 20 and check the alignment state of the substrate 10 attached to the substrate carrier 20 based on the laser beam. The processing part 320 may include various known optical systems, a laser beam oscillation unit, a camera and sensor for checking an alignment state, and the like.

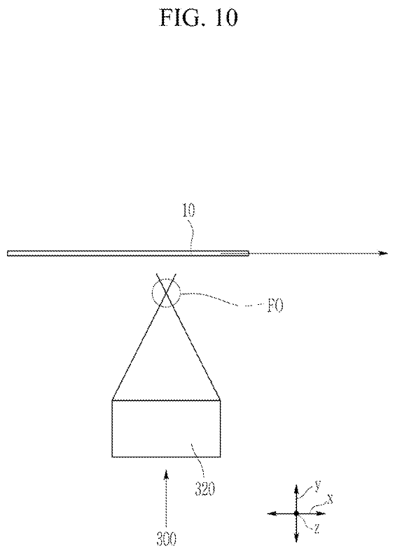

FIG. 10 is a view showing an example of a processing part of an etching part of a substrate etching apparatus according to an embodiment.

As an example of the processing part 320, the processing part 320 performs auto focus that automatically adjusts a focus FO of the laser beam irradiated on the substrate 10 by using the flatness of the substrate 10 measured by the measuring part 310. Here, the auto focus may mean adjusting the focus FO of a laser beam to the surface of the substrate 10, but is not limited thereto.

As described above, the substrate etching apparatus according to an embodiment supports the substrate carrier 20 in the vertical direction z while the substrate 10 is attached to the substrate carrier 20, and then etches the substrate 10, thereby there is no need to separate the substrate 10 from the substrate carrier 20 and rotate the substrate 10 around the horizontal direction x.

That is, there is no need to separate the substrate 10 attached to the substrate carrier 20 transferred from the previous process from the substrate carrier 20 and no need to rotate the substrate 10 around the horizontal direction x so that the surface of the substrate 10 faces downward, and the substrate etching apparatus performing the etching process in the state in which the substrate 10 is attached to the substrate carrier 20 and supported in the vertical direction z is provided.

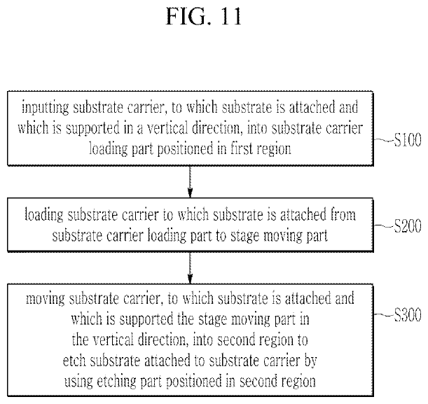

Hereinafter, a substrate etching method according to another embodiment is described with reference to FIG. 11 to FIG. 19. The substrate etching method according to another embodiment may be performed using the substrate etching apparatus according to an embodiment described above, but is not limited thereto.

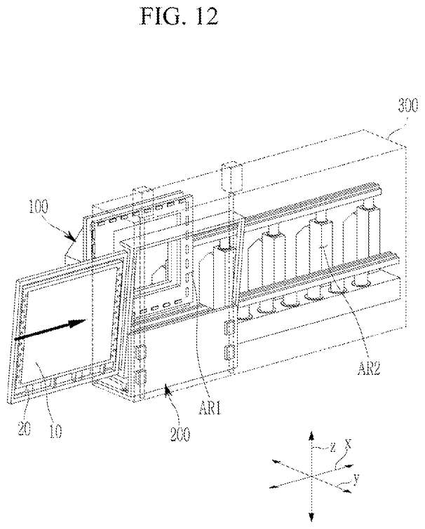

FIG. 11 is a flowchart showing a substrate etching method according to another embodiment. FIG. 12 to FIG. 19 are perspective views to explain a substrate etching method according to another embodiment.

Referring to FIG. 11 and FIG. 12, a substrate carrier 20, to which a substrate 10 is attached and which is supported in a vertical direction z, is loaded into a substrate carrier loading part 200 positioned in a first region AR1 in a horizontal direction x (S100).

In detail, referring to FIG. 12, the substrate carrier 20 to which the substrate 10 is attached from the previous process is put into the substrate carrier loading part 200 in a state of tilting at a predetermined angle with respect to the vertical direction z.

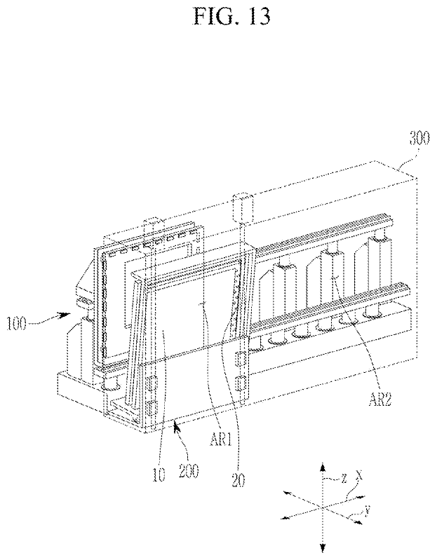

Next, referring to FIG. 13 to FIG. 16, the substrate carrier 20 to which the substrate 10 is attached is loaded from the substrate carrier loading part 200 into the stage moving part 100 (S200).

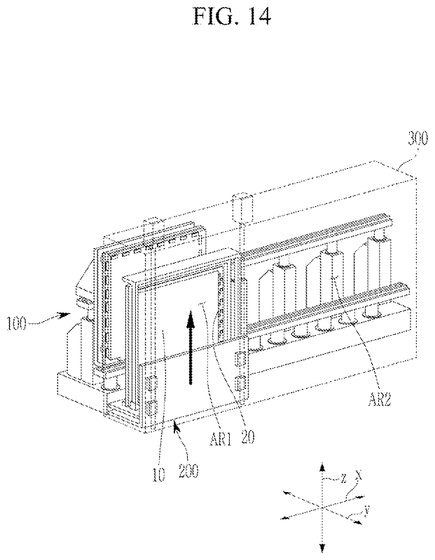

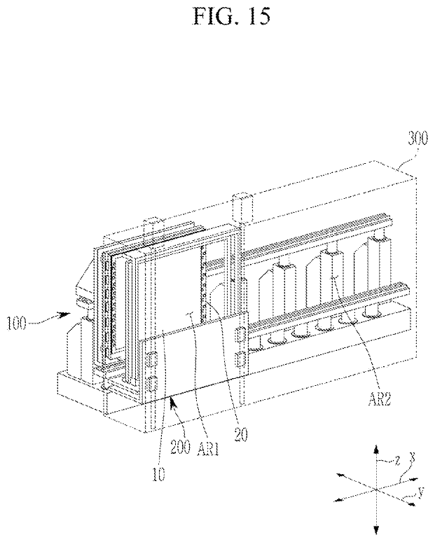

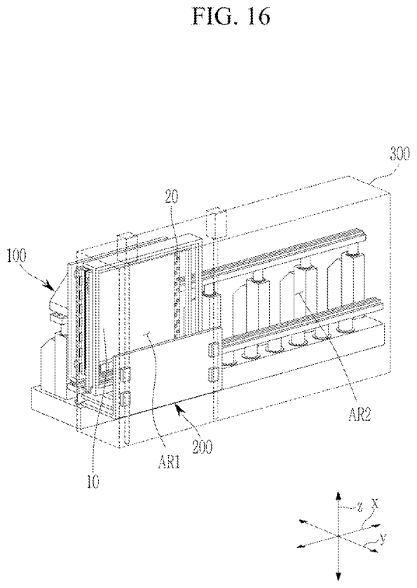

Specifically, referring to FIG. 13, the substrate carrier loading part 200 rotates the substrate carrier 20 to which the substrate 10 is attached around the horizontal direction x to be aligned in the vertical direction z. Also, referring to FIG. 14, the substrate carrier loading part 200 moves the substrate carrier 20 in the vertical direction z so that the substrate carrier 20 to which the substrate 10 is attached corresponds to the stage part 110 of the stage moving part 100. Also, referring to FIG. 15 and FIG. 16, the substrate carrier loading part 200 moves the substrate carrier 20 to which the substrate 10 is attached in the crossing direction y to be loaded into the stage part 110 of the stage moving part 100. The substrate carrier 20 to which the substrate 10 is attached is supported on the stage moving part 100 in the vertical direction z. At this time, the carrier frame surrounding the periphery of the substrate carrier 20 may be separated from the substrate carrier 20 and positioned on the substrate carrier loading part 200.

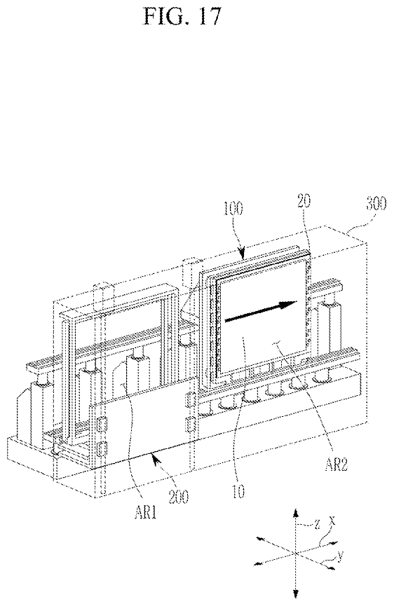

Next, referring to FIG. 17 to FIG. 19, the substrate carrier 20, to which the substrate 10 is attached and which is supported by the stage moving part 100 in the vertical direction z, moves in the horizontal direction x to arrive at the second region AR2 to etch the substrate 10 attached to the substrate carrier 20 by using an etching part 300 (S300).

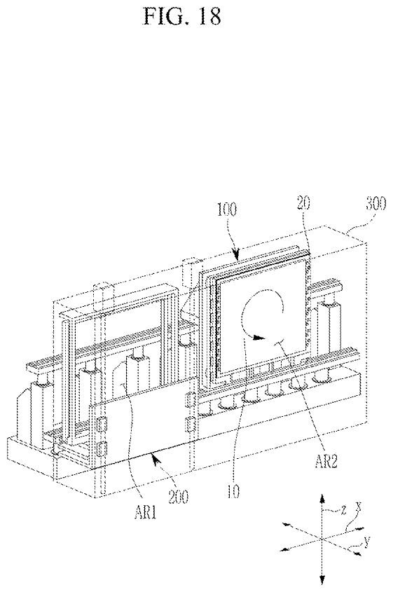

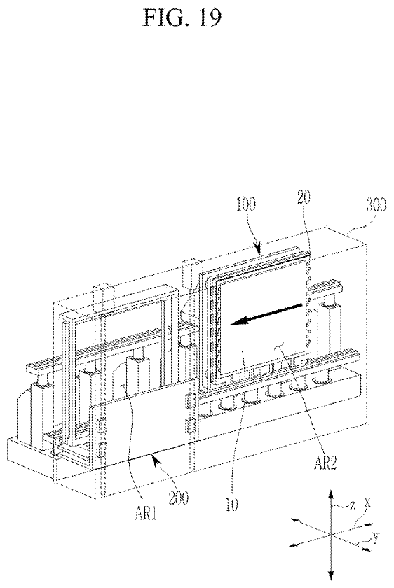

In detail, referring to FIG. 17, the stage moving part 100 moves in the horizontal direction x, and the substrate carrier 20, to which the substrate 10 is attached and which is supported to the stage moving part 100 in the vertical direction z, moves into the second region AR2 adjacent to the first region AR1 in the horizontal direction x. Also, referring to FIG. 18, the substrate 10 attached to the substrate carrier 20 moved to the second region AR2 in which the etching part 300 is positioned may be aligned with respect to an optical system of the etching part 300 by using an alignment mark, etc. Also, referring to FIG. 19, the substrate 10 attached to the substrate carrier 20 is etched by using the etching part 300 positioned on the second region AR2, the etching condition is checked, and then the substrate carrier 20 to which the substrate 10 is attached moves into the first region AR1 again in the horizontal direction x. The etching part 300 may perform auto focus on the laser beam irradiated to the substrate 10 by using the flatness of the substrate 10 attached to the substrate carrier 20 with respect to the plane defined by the horizontal direction x and the vertical direction z (i.e., flatness in the vertical direction z). In addition, the substrate carrier 20 to which the substrate 10 that the etching is completed is attached may be transferred to the next process after being put back into the substrate carrier loading part 200 in the first region AR1.

As above-described, the substrate etching method according to another embodiment supports the substrate carrier 20 in the vertical direction z in the state that the substrate 10 is attached to the substrate carrier 20 to etch the substrate 10, thereby there is no need to separate the substrate 10 from the substrate carrier 20 and rotate the substrate 10 around the horizontal direction x.

That is, there is no need to separate the substrate 10 attached to the substrate carrier 20 transferred from the previous process from the substrate carrier 20 and rotate the substrate 10 around the horizontal direction x so that the surface of the substrate 10 faces downward, and the substrate etching method performing the etching process in the state in which the substrate 10 is attached to the substrate carrier 20 and supported in the vertical direction z. is provided.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A substrate etching apparatus comprising:
a stage moving part configured to support in a vertical direction a substrate carrier to which a substrate is attached and move in a horizontal direction the substrate carrier to which the substrate is attached;
a substrate carrier loading part positioned in a first region in the horizontal direction and configured to load the substrate carrier, to which the substrate is attached, to the stage moving part; and
an etching part positioned in a second region adjacent to the first region in the horizontal direction and configured to etch the substrate attached to the substrate carrier supported on the stage moving part in the vertical direction.

2. The substrate etching apparatus of claim 1, wherein
the stage moving part includes:
a stage part configured to support the substrate carrier in the vertical direction;
a frame part configured to guide the stage part in the horizontal direction; and
a moving part configured to support the stage part and be guided by the frame part to move in the horizontal direction.

3. The substrate etching apparatus of claim 2, wherein
the stage part is not rotated.

4. The substrate etching apparatus of claim 2, wherein
the frame part includes:
a first rail part positioned on a lower rear of the stage part, extending in the horizontal direction and configured to support the moving part;
a second rail part positioned on an upper rear of the stage part, extending in the horizontal direction and configured to support the moving part; and
a fixing part configured to fix the first rail part and the second rail part.

5. The substrate etching apparatus of claim 4, wherein
the first rail part and the second rail part support the moving part in the vertical direction.

6. The substrate etching apparatus of claim 4, wherein
the first rail part supports the moving part in the vertical direction, and
the second rail part supports the moving part in a cross direction intersecting the vertical direction and the horizontal direction.

7. The substrate etching apparatus of claim 4, wherein
the first rail part and the second rail part support the moving part in a cross direction intersecting the vertical direction and the horizontal direction.

8. The substrate etching apparatus of claim 4, wherein
the fixing part includes at least one of a granite frame, a rectangular tube frame, and a solid frame.

9. The substrate etching apparatus of claim 1, wherein
the substrate carrier loading part rotates the substrate carrier to which the substrate is attached around the horizontal direction to be aligned in the vertical direction.

10. The substrate etching apparatus of claim 9, wherein
the substrate carrier to which the substrate is attached is put into the substrate carrier loading part in a tilted state with a predetermined angle with respect to the vertical direction.

11. The substrate etching apparatus of claim 9, wherein
the substrate carrier loading part includes:
a supporting part configured to support the substrate carrier;
a rotation part configured to rotate a lower portion of the supporting part around the horizontal direction; and
a tilt driving part configured to move an upper part of the supporting part in a cross direction intersecting the vertical direction and the horizontal direction.

12. The substrate etching apparatus of claim 11, wherein
the substrate carrier loading part moves the substrate carrier to which the substrate is attached in the vertical direction and then in the cross direction such that the substrate carrier is loaded to the stage moving part.

13. The substrate etching apparatus of claim 1, wherein
the etching part uses a laser beam to etch the substrate attached to the substrate carrier.

14. The substrate etching apparatus of claim 13, wherein
the etching part includes:
a measuring part configured to measure a flatness of the substrate attached to the substrate carrier in the vertical direction and check the etching state of the substrate by the laser beam; and
a processing part configured to irradiate the laser beam to the substrate attached to the substrate carrier and check alignment of the substrate attached to the substrate carrier based on the laser beam.

15. The substrate etching apparatus of claim 14, wherein
the processing part performs auto focus on the laser beam irradiated on the substrate using the flatness of the substrate measured by the measuring part.

16. A substrate etching method comprising:
inputting a substrate carrier, to which a substrate is attached and which is supported in a vertical direction, into a substrate carrier loading part positioned in a first region in a horizontal direction;
loading the substrate carrier to which the substrate is attached from the substrate carrier loading part to a stage moving part; and
moving the substrate carrier, to which the substrate is attached and which is supported to the stage moving part in the vertical direction, into a second region adjacent to the first region in the horizontal direction to etch the substrate attached to the substrate carrier by using an etching part positioned in the second region.

17. The substrate etching method of claim 16, wherein
the substrate carrier to which the substrate is attached is put into the substrate carrier loading part in a tilted state with a predetermined angle with respect to the vertical direction.

18. The substrate etching method of claim 17, wherein
the substrate carrier loading part rotates the substrate carrier to which the substrate is attached around the horizontal direction to be aligned in the vertical direction, moves the substrate carrier in the vertical direction, and moves the substrate carrier in a cross direction intersecting the vertical direction and the horizontal direction such that the substrate carrier is loaded to the stage moving part.

19. The substrate etching method of claim 16, wherein
the etching part uses a laser beam to etch the substrate attached to the substrate carrier.

20. The substrate etching method of claim 19, wherein
the etching part performs auto focus on the laser beam irradiated onto the substrate by using a flatness of the substrate attached to the substrate carrier.
